(19) United States
(12) Patent Application Publication
(10) Pub. No.: US 2026/0134907 A1
(43) Pub. Date: May 14, 2026

(54) FAST LOW-LEAKAGE SRAM CELL

(71) Applicant: OMNIVISION TECHNOLOGIES, INC., Santa Clara, CA (US)

(72) Inventors: Jingjun Yi, San Jose, CA (US); Qing Qin, Sunnyvale, CA (US); Tiejun Dai, Santa Clara, CA (US); Sunny Yat-San Ng, San Jose, CA (US)

(21) Appl. No.: 18/943,789

(22) Filed: Nov. 11, 2024

(51) Int. Cl. G11C 11/412; G11C 11/419; H10B 10/00

(52) U.S. Cl. CPC G11C 11/412; G11C 11/419; H10B 10/12

(57) ABSTRACT

Fast low-leakage SRAM cells, such as for digital display systems, are disclosed herein. In one embodiment, a bit storage circuit includes a latch, a first transistor, and a second transistor. The latch can have a pair of cross-coupled inverters including first and second inverters. The first transistor can have a source coupled to receive a first control signal, a drain coupled to an input of the first inverter, and a gate coupled to receive a wordline select control signal. The second transistor can have a source coupled to receive a second control signal different from the first control signal, a drain coupled to an input of the second inverter, and a gate coupled to receive the wordline select control signal.

### TECHNICAL FIELD

This disclosure relates generally to bit storage devices and associated devices, systems, and methods. For example, several embodiments described in detail below are directed to fast, low-leakage static random-access memory (SRAM) cells, such as for digital displays and/or display pixel circuitry.

### BACKGROUND

SRAM cells are integral components in digital displays, providing a fast and reliable means of storing pixel data. Each SRAM cell typically includes transistors configured to hold a single bit of data and directly control the state of a corresponding pixel. In digital displays such as LCDs and OLEDs, the SRAM cells are used to maintain on or off statuses of individual pixels, ensuring a correct image or video frame is displayed. Unlike dynamic RAM (DRAM), SRAM does not require constant refreshing, making it ideal for applications where quick access to stored data and stability are crucial, particularly in high-performance graphics or real-time image processing.

SRAM cells are valued for their low-latency data retrieval and high speed, enabling displays to render images smoothly and without delay. These characteristics make them a preferred choice for devices requiring quick response times, such as smartphones, tablets, and high-resolution monitors. Their stable storage capabilities help to ensure consistent pixel performance, enhancing the overall quality of digital displays.

### BRIEF DESCRIPTION OF THE DRAWINGS

Non-limiting and non-exhaustive embodiments of the present technology are described below with reference to the following figures, in which like or similar reference numbers are used to refer to like or similar components throughout unless otherwise specified.

FIG. 1 is a partially schematic diagram of a digital display system configured in accordance with various embodiments of the present technology.

FIG. 2 is a partially schematic diagram of a display pixel array of the digital display system of FIG. 1.

FIG. 3 is a partially schematic diagram of a bit storage circuit configured in accordance with various embodiments of the present technology.

FIG. 4 is a partially schematic diagram of another bit storage circuit configured in accordance with various embodiments of the present technology.

FIG. 5 is an example timing diagram of a bit storage circuit in accordance with various embodiments of the present technology.

FIG. 6 is a partially schematic diagram of still another bit storage circuit configured in accordance with various embodiments of the present technology.

Skilled artisans will appreciate that elements in the figures are illustrated for simplicity and clarity and are not necessarily drawn to scale. For example, the dimensions of some of the elements in the figures may be exaggerated relative to other elements to aid in understanding of various aspects of the present technology. In addition, common but well-understood elements or methods that are useful or necessary in a commercially feasible embodiment are often not depicted in the figures, or described in detail below, to avoid unnecessarily obscuring the description of various aspects of the present technology.

### DETAILED DESCRIPTION

The present disclosure relates generally to bit storage devices and associated devices, systems, and methods. For example, several embodiments described herein are directed to fast, low-leakage SRAM cells for display pixels and/or digital display systems. As a specific example, several embodiments of the present technology are directed to SRAM cells that are expected to exhibit lower amounts of leakage current in comparison to other SRAM cells and without compromising speed. Such cells can include a latch and a plurality of transistors coupled to the latch. In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) may be used herein for ease of description to describe one element's or feature's relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

It will be understood that, although the terms first, second, third, etc., may be used in the disclosure and claims to describe various elements, these elements should not be limited by these terms and should not be used to determine the process sequence or formation order of associated elements. Unless otherwise indicated, these terms are merely used to distinguish one element from another element. Thus, a first element discussed below could be termed a second element without departing from the teachings of the disclosed embodiments.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

### A. Overview

As discussed above, many digital display systems employ bit storage circuits (e.g., SRAM cells) to maintain an on status or an off status of individual pixels, ensuring a correct image or video frame is displayed. Although these digital display systems offer great image and video display capabilities, one of the limitations with such digital display systems is that normal bit storage circuits, particularly SRAM cells in modern high-resolution displays, exhibit high leakage current and high power consumption. Leakage current occurs when unintended current flows through transistors, even when the cell is not being actively accessed. This can lead to power inefficiency, as leakage increases power consumption, which is especially problematic in battery-operated devices like smartphones and tablets. Leakage current in an SRAM cell also poses a risk of data corruption. As demands for higher display resolution and density increase, minimizing leakage current in bit storage circuits/SRAM cells becomes critical for improving energy efficiency, extending battery life, and ensuring data integrity. Attempts to provide digital display systems with low leakage current have, thus far, resulted in compromised solutions that fail to meet speed, size, and/or other design/performance requirements.

It is appreciated that bit storage circuits configured in accordance with various embodiments of the present technology address at least some of the issues discussed above. For example, a bit storage circuit (e.g., an SRAM cell) disclosed herein can include (i) a latch including two inverters and (ii) transistors that selectively couple the inputs of the two inverters to respective control signals. In some embodiments, the bit storage circuit further includes a transistor coupled between each pair of transistors that form a respective inverter.

Thus, as will be shown and described in the various examples below, a bit storage circuit configured in accordance with various embodiments of the present technology can include a latch, a first transistor, and a second transistor. The latch can have a pair of cross-coupled inverters including a first inverter and a second inverter. The first transistor can have a source coupled to receive a first control signal, a drain coupled to an input of the first inverter, and a gate coupled to receive a wordline select control signal. The second transistor can have a source coupled to receive a second control signal different from the first control signal, a drain coupled to an input of the second inverter, and a gate coupled to receive the wordline select control signal. The first inverter can include (i) a third transistor having a source coupled to a supply voltage, a gate coupled to the input of the first inverter, and a drain, and (ii) a fourth transistor having a source coupled to ground, a gate coupled to the input of the first inverter, and a drain. The bit storage circuit can further include a fifth transistor selectively coupling the drain of the third transistor to the drain of the fourth transistor, and having a gate coupled to receive the first control signal. The second inverter can include (i) a sixth transistor having a source coupled to a supply voltage, a gate coupled to the input of the second inverter, and a drain, and (ii) a seventh transistor having a source coupled to ground, a gate coupled to the input of the second inverter, and a drain. The bit storage circuit can further include an eighth transistor selectively coupling the drain of the sixth transistor to the drain of the seventh transistor, and having a gate coupled to receive the second control signal.

The present technology is expected to offer several advantages. For example, by receiving control signals via the sources (as opposed to the gates) of select transistors, bit storage circuits of the present technology are expected to allow voltage levels of the control signals to be reduced, leading to reduced power consumption and faster write operation speeds. Also, bit storage circuits of the present technology are expected to prevent (or at least reduce the effects of) old data written to the latch contending with new data being written to the latch. As another example, during a write operation for a bit storage circuit of the present technology, a transistor coupled between a pair of transistors forming an inverter of the bit storage circuit can be at least partially deactivated to cut off (or at least weaken) a pull-up path between a supply voltage and the corresponding bitline. Cutting off or weakening the pull-up path during write operations is expected to decrease power consumption of the bit storage circuit and/or increase the speed at which the bit storage circuit is written with data. Additionally, or alternatively, bit storage circuits of the present technology are expected to compensate for (or replace) leakage current from the corresponding latches, including on selected and unselected latches during write operations. For example, bit storage circuits of the present technology can include transistors that can conduct current from the supply voltage to compensate for current that leaks out of the corresponding latch.

### B. Selected Embodiments of Bit Storage Circuits, and Associated Devices, Systems, and Methods

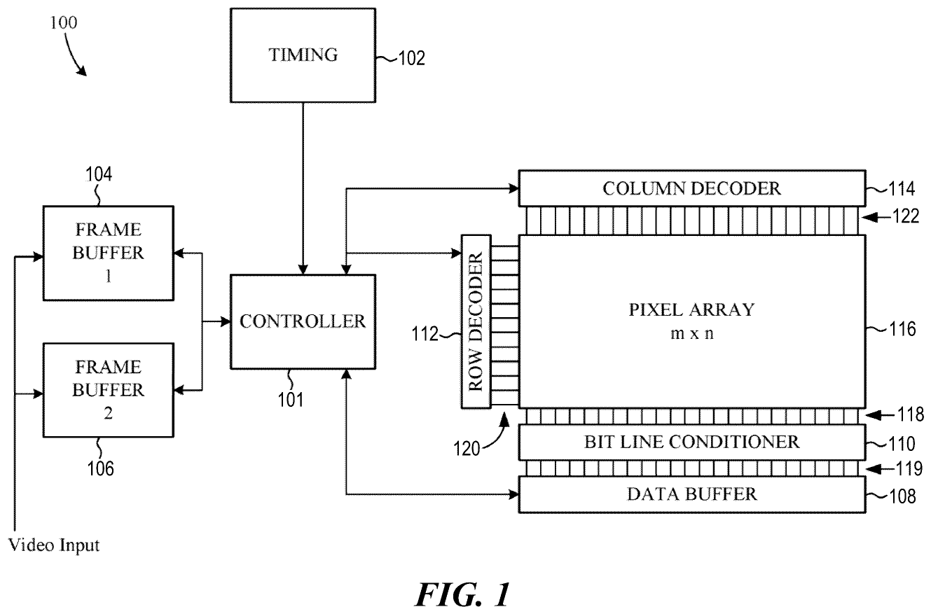

FIG. 1 is a partially schematic diagram of a digital display system 100 (“system 100”) configured in accordance with various embodiments of the present technology. The system 100 includes a controller 101, a timing generator 102, a first frame buffer 104, a second frame buffer 106, a data buffer 108, a bitline conditioner 110, a row decoder 112, a column decoder 114, and a display pixel array 116. It is appreciated that in other embodiments, the system 100 can omit one or more of the illustrated components and/or include additional components.

The controller 101 can be coupled to receive timing signals from the timing generator 102, and can be configured to use those timing signals to (a) coordinate the transfer of video data into the frame buffers 104 and 106, and (b) drive the pixels of the display pixel array 116 to display images corresponding to the video data. For example, the controller 101 can “set” (e.g., turn on) and “clear” (e.g., turn off or reset) each pixel of the display (e.g., so that each pixel is turned on for a portion of a predefined frame time). The amount of time that a particular pixel is turned on can be based on the value of a corresponding multi-bit intensity value stored in the frame buffer 104 or 106.

The first frame buffer 104 and the second frame buffer 106 can each be configured to receive an entire frame of video data and used by the controller 101 in an alternating manner. For example, while one frame of video data from the first frame buffer 104 is being used (e.g., by the controller 101) to determine the signals asserted on the display pixel array 116, a subsequent frame of video data can be loaded into the second frame buffer 106. Then, while the frame of video data from the second frame buffer 106 is being used (e.g., by the controller 101) to determine the signals asserted on the display pixel array 116, another subsequent frame of video data can be loaded into the first frame buffer 104, and so on.

In the illustrated embodiment, the display pixel array 116 is an m×n array of individual pixels, wherein m is the number of columns and n is the number of rows. The display pixel array 116 can display video (e.g., a rapid series of images) by turning the individual pixels on for predetermined portions of a frame period corresponding to particular desired intensities. The individual pixels can be turned on and off by latching data bits asserted on bitlines 118 by the bitline conditioner 110. The pixels can be configured to latch the data bits being asserted on the bitlines 118 by row enable signals from the row decoder 112 and column enable signals from the column decoder 114.

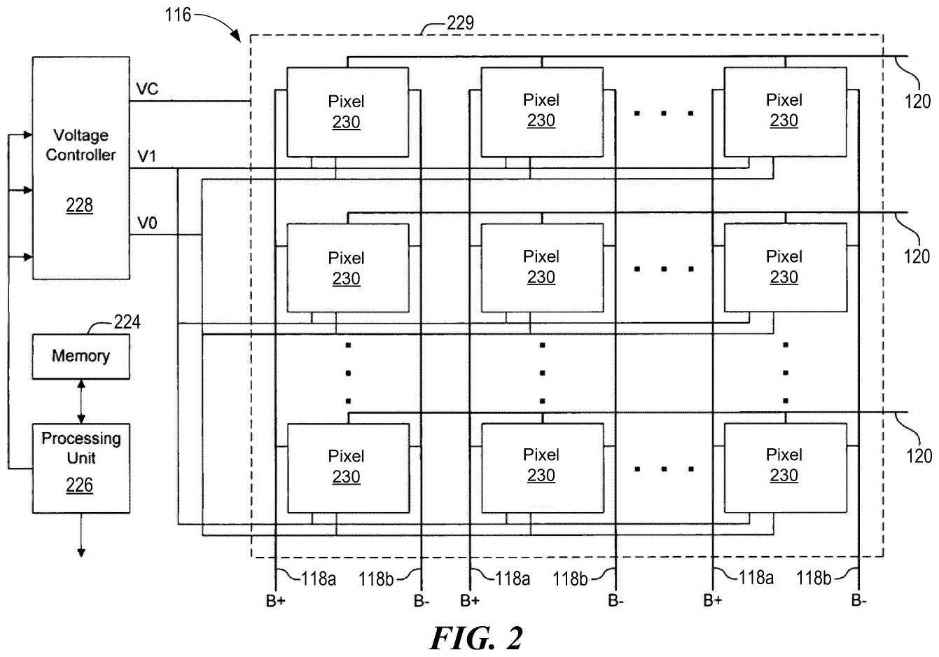

The data buffer 108 can be configured to receive lines of data bits that, in the illustrated example, turn individual pixels of the display pixel array 116 on and off. The bitline conditioner 110 can be configured to (a) receive, via data lines 119, data bits from the data buffer 108 in the form of low power electrical states and (b) assert more powerful signals onto the bitlines 118 and into the display pixel array 116, depending on the values of the original data bits. The internal circuitry and operation of the display pixel array 116 is described in further detail below with reference to FIGS. 2-6.

The row decoder 112 and the column decoder 114, responsive to addresses and control signals from the controller 101, can enable the pixels of the display pixel array 116 to latch data bits being asserted on the bitlines 118 by the data buffer 108 and the bitline conditioner 110. In order for a particular pixel to be enabled, it must be enabled by both the column decoder 114 and the row decoder 112.

The row decoder 112 can be coupled between the controller 101 and the display pixel array 116, and can be configured to selectively assert row enable signals onto wordlines 120 connected to the various pixel rows of the display pixel array 116. A row enable signal (also referred to herein as a “wordline enable signal WL” or as a “write enable signal WL”) enables each pixel of a selected row to load a data bit being asserted on a corresponding bitline 118 by the data buffer 108. More specifically, the row decoder 112 can receive a series of row addresses from the controller 101, and can sequentially assert a row enable signal on a respective wordline 120 corresponding to each received row address.

The column decoder 114 can be coupled between the controller 101 and the display pixel array 116, and can be configured to, in response to control signals from the controller 101, selectively assert column enable signals (also referred to herein as “set control signal S” and “clear control signal “C”) onto various pixel column lines 122 of the display pixel array 116. In some embodiments, the row decoder 112 can assert a row enable signal on one wordline 120 at a time, and the column decoder 114 can simultaneously assert control signals on some, all, or none of the pixel column lines 122. Not asserting a column enable signal on a particular pixel column line 122 can allow an associated pixel of an enabled row to hold its prior data, notwithstanding the row enable signal being asserted on its wordline 120 by the row decoder 112.

FIG. 2 is a partially schematic diagram of the display pixel array 116 of the system 100 of FIG. 1. As shown, the display pixel array 116 includes a plurality of pixel cells 230 (also referred to herein as “pixels 230” or “pixel circuits 230”) arranged in columns and rows, a common transparent electrode 229 that overlays the entire array 116 of the pixels 230, a memory device 224, a processing unit 226 and a voltage controller 228. The memory device 224, the processing unit 226, and/or the voltage controller 228 can be disposed on or off chip with respect to the array 116 of pixels 230. It is appreciated that in other embodiments, the display pixel array 116 can omit one or more of the illustrated components and/or include additional components.

In the illustrated embodiment, each of the pixels 230 is coupled to (i) a first supply voltage V0 in the voltage controller 228, (ii) a second supply voltage V1 in the voltage controller 228, (iii) a corresponding one of first bitlines B+ 118a, (iv) a corresponding one of second bitlines B− 118b, and (v) a corresponding one of the wordlines 120. As shown, the pixels 230 of a same column can be coupled to a same one of the first bitlines B+ 118a and a same one of the second bitlines B− 118b, and the pixels 230 of a same row can be coupled to a same one of the wordlines 120. In some embodiments, the pixels 230 are formed in an integrated monolithic silicon backplane, overlaid with a plurality of pixel mirrors. A layer of liquid crystal material can be interposed between the pixel mirrors and the common transparent electrode 229. The common transparent electrode 229 can be composed of Indium-Tin-Oxide and/or other suitable material, and can be coupled to a common supply voltage VC in the voltage controller 228.

As discussed in further detail herein, each of the pixels 230 can include a bit storage circuit (e.g., including an SRAM cell or another type of memory element) that stores a single bit of information representing an on (e.g., active) state or an off (e.g., inactive) state of the pixel 230. The stored bits directly influence the brightness, color, and/or transparency of the pixels 230. By maintaining the pixel state even when not actively accessed, the bit storage circuit can ensure stable and continuous image rendering.

The memory device 224 can include a computer-readable medium (e.g., RAM, ROM, etc.) having code or instructions (e.g., data and commands) embodied therein for causing the processing unit 226 to implement the various methods and driving schemes described herein. The processing unit 226 can (i) receive the instructions from the memory device 224 (e.g., via a memory bus), (ii) provide internal voltage control signals to the voltage controller 228 (e.g., via a voltage control bus), and (iii) provide data control signals to the pixels 230 (e.g., via a data control bus).

In operation, rows of data bits can be asserted on the first bitlines B+ 118a and the second bitlines B− 118b, and assertion of a write enable signal on the wordline 120 of a particular row can cause the asserted bits to be written into the pixels 230 in that row. In this manner, data bits can be sequentially written to each pixel 230 of the entire display. Responsive to control signals received from the processing unit 226, the voltage controller 228 can provide predetermined or variable voltages to the pixels 230 via the first supply voltage V0 and the second supply voltage V1. The voltage controller 228 can also assert predetermined voltages on the common electrode 229 via the common supply voltage VC. The processing unit 226 can provide control signals to the voltage controller 228 and/or directly to the pixels 230. For example, the processing unit 226 can provide set, clear, and/or other control signals to transistors included in the bit storage circuits of the pixels 230.

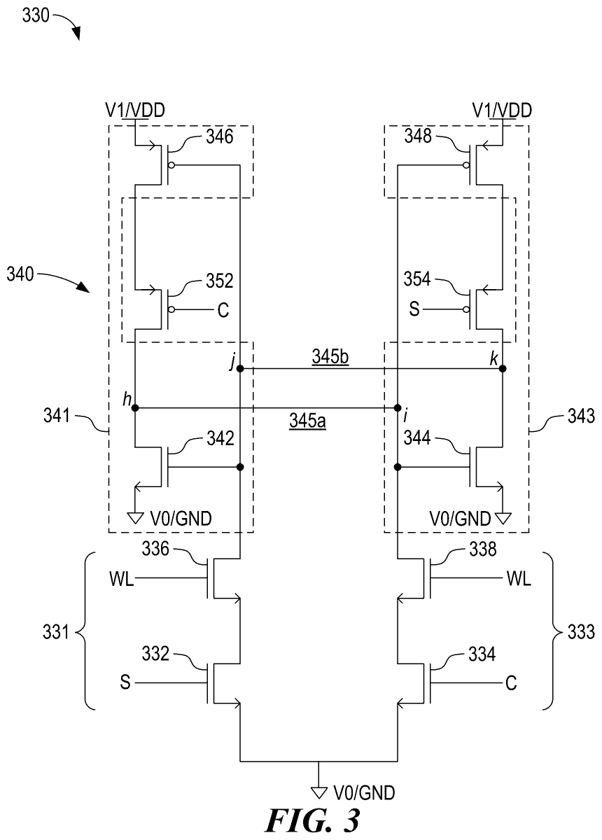

FIG. 3 is a partially schematic diagram of a bit storage circuit 330 configured in accordance with various embodiments of the present technology. It is appreciated that the bit storage circuit 330 can be an example of a bit storage circuit included in each of the pixels 230 of FIG. 2 and/or in other pixels configured in accordance with various embodiments of the present technology. In some embodiments, the bit storage circuit 330 can include an SRAM cell. For example, the bit storage circuit 330 can include a latch 340 coupled between a first supply voltage V1 (hereinafter referred to as “VDD” for the sake of example and clarity) and a second supply voltage V0 (hereinafter referred to as “ground” for the sake of example and clarity). The bit storage circuit 330 can further include (i) a first and second pull-down legs 331, 333 that are each coupled between the latch 340 and ground, and (ii) transistors 352, 354.

In the illustrated embodiment, the latch 340 comprises a pair of cross-coupled inverters. The pair of cross-coupled inverters includes a first inverter 341 and a second inverter 343. The first inverter 341 includes (i) a transistor 342, a transistor 346, an input j, and an output h. In addition, the second inverter 343 includes a transistor 344, a transistor 348, an input i, and an output k.

Referring to the first inverter 341, the transistor 342 has a source coupled to ground, a drain coupled to the output h and to a drain of the transistor 352, and a gate coupled to the input j and to a gate of the transistor 346. In addition, the transistor 346 includes a source coupled to VDD, the gate coupled to the input j and to the gate of the transistor 342, and a drain coupled to a source of the transistor 352. In some embodiments, the transistor 342 is an NMOS transistor, and the transistor 346 is a PMOS transistor.

Referring now to the second inverter 343, the transistor 344 has a source coupled to ground, a drain coupled to the output k and to a drain of the transistor 354, and a gate coupled to the input i and to a gate of the transistor 348. In addition, the transistor 348 includes a source coupled to VDD, the gate coupled to the input i and to the gate of the transistor 344, and a drain coupled to a source of the transistor 354. In some embodiments, the transistor 344 is an NMOS transistor, and the transistor 348 is a PMOS transistor. The input i of the second inverter 343 can be coupled to the output h of the first inverter 341 at a first latch node 345a (“the first node 345a”), and the output k of the second inverter 343 can be coupled to the input j of the first inverter 341 at a second latch node 345b (“the second node 345b”).

The first pull-down leg 331 of the bit storage circuit 330 can include a transistor 332 and a transistor 336. In the illustrated embodiment, the transistor 332 includes a source coupled to ground, a drain coupled to a source of the transistor 336, and a gate coupled to receive a first (set) control signal S (e.g., from one of the first bitlines B+ 118a of FIGS. 1 and 2) such that the transistor 332 can selectively couple the transistor 336 to ground based at least in part on a state of the first control signal S. In addition, the transistor 336 includes a drain coupled to the input j of the first inverter 341, the gates of the transistors 342, 346 of the first inverter 341, and the output k of the second inverter 343. The transistor 336 further includes a gate coupled to receive a row enable signal WL such that the transistor 336 can selectively couple the input j of the first inverter 341 to the transistor 332 and/or ground (via the transistor 332) based at least in part on a state of the row enable signal WL. In some embodiments, the transistors 332, 336 can be NMOS transistors.

The second pull-down leg 333 of the bit storage circuit 330 is similar to the first pull-down leg 331. For example, the second pull-down leg 333 can include a transistor 334 and a transistor 338. In the illustrated embodiment, the transistor 334 includes a source coupled to ground, a drain coupled to a source of the transistor 338, and a gate coupled to receive a second (clear/reset) control signal C (e.g., from one of the second bitlines B− 118b of FIGS. 1 and 2) such that the transistor 334 can selectively couple the transistor 338 to ground based at least in part on a state of the second control signal C. In addition, the transistor 338 includes a drain coupled to the input i of the second inverter 343, the gates of the transistors 344, 348 of the second inverter 343, and the output h of the first inverter 341. The transistor 338 further includes a gate coupled to receive the row enable signal WL such that the transistor 338 can selectively couple the input i of the second inverter 343 to the transistor 334 and/or ground (via the transistor 334) based at least in part on a state of the row enable signal WL. In some embodiments, the transistors 334, 338 can be NMOS transistors.

As shown, the transistor 352 can be positioned between (e.g., coupled in series with) the transistors 346, 342 forming the first inverter 341. For example, the transistor 352 can include a drain coupled to the output h of the first inverter 341 and to the drain of the transistor 342, and a source coupled to the drain of the transistor 346. In addition, the transistor 352 can include a gate coupled to receive the second control signal C such that the transistor 352 can selectively couple the transistor 346 and/or VDD to the output h of the first inverter 341. In some embodiments, the transistor 352 can include a PMOS transistor.

Similarly, the transistor 354 can be positioned between (e.g., coupled in series with) the transistors 348, 344 forming the second inverter 343. For example, the transistor 354 can include a drain coupled to the output k of the second inverter 343 and to the drain of the transistor 344, and a source coupled to the drain of the transistor 348. In addition, the transistor 354 can include a gate coupled to receive the first control signal S such that the transistor 354 can selectively couple the transistor 348 and/or VDD to the output k of the second inverter 343. In some embodiments, the transistors 354 can include a PMOS transistor.

In operation, the first and second control signals S and C and the row enable signal WL can be controlled to write data bits to the bit storage circuit 330. For example, to set a data bit of “1” onto the first node 345a, the write enable signal WL and the first control signal S can be asserted to activate the transistors 336, 338 and the transistor 332, respectively. It is appreciated that only one of the first and second control signals S or C may be asserted at any given time. Thus, when the first control signal S is asserted, the second control signal C can be unasserted such that the transistor 334 is deactivated. As a result of the transistors 332, 336 being activated, the input j of the first inverter 341 can be coupled to ground via the first pull-down leg 331. In turn, the low voltage level of ground can deactivate the transistor 342 (e.g., an NMOS transistor) and can activate the transistor 346 (e.g., a PMOS transistor). The low state of the second control signal C can activate the transistor 352 (e.g., a PMOS transistor). The activated transistors 346, 352 can thus couple the output h of the first inverter 341 to VDD, thereby pulling the first node 345a and the input i of the second inverter 343 toward the high voltage level of VDD. As the input i is pulled high, the transistor 344 (e.g., an NMOS transistor) can be activated and the transistor 348 (e.g., a PMOS transistor) can be deactivated. The asserted state of the first control signal S can deactivate the transistor 354 (e.g., a PMOS transistor), thereby cutting off the output k from the transistor 348 and/or VDD. The activated transistor 344 can couple the output k of the second inverter 343 to ground, thereby pulling the second node 345b and the input j of the first inverter 341 down toward the low voltage level of ground. In this manner, the latch 340 of the bit storage circuit 330 can be written such that a voltage at the first node 345a is in a first state (e.g., a high voltage state, or “1”) and a voltage at the second node 345b is in a second state (e.g., a low voltage state, or “0”).

The bit storage circuit 330 can be operated in a similar manner to set a data bit of “0” onto the first node 345a (e.g., to reset or clear the latch 340). More specifically, the write enable signal WL and the second control signal C can be asserted to activate the transistors 336, 338 and the transistor 334, respectively, and to deactivate the transistor 352 (thereby cutting off the output h from the transistor 346 and/or VDD). As discussed above, in some embodiments, only one of the first and second control signals S or C may be asserted at any given time. Thus, when the second control signal C is asserted, the first control signal S can be unasserted such that the transistor 332 is deactivated and the transistor 354 is activated. As a result of the transistors 334, 338 being activated, the input i of the second inverter 343 can be coupled to ground via the second pull-down leg 333. In turn, the low voltage level of ground can deactivate the transistor 344 (e.g., an NMOS transistor) and can activate the transistor 348 (e.g., a PMOS transistor). The activated transistors 348, 354 can thus couple the output k of the second inverter 343 to VDD, thereby pulling the second node 345b and the input j of the first inverter 341 toward the high voltage level of VDD. As the input j is pulled high, the transistor 342 (e.g., an NMOS transistor) of the first inverter 341 can be activated and the transistor 346 (e.g., a PMOS transistor) of the first inverter 341 can be deactivated. The activated transistor 342 can couple the output h of the first inverter 341 to ground, thereby pulling the first node 345a and the input i of the second inverter 343 down toward the low voltage level of ground. In this manner, the latch 340 of the bit storage circuit 330 can be written (e.g., reset or cleared) such that a voltage at the first node 345a is in the second state (e.g., a low voltage state, or “0”) and a voltage at the second node 345b is in the first state (e.g., a high voltage state, or “1”).

The inclusion of the transistors 352, 354 is expected to increase operating speeds of the associated SRAM. For example, without the transistor 354, if the first node 345a was previously storing a low value and the set control signal S is asserted, the transistor 348 may remain activated for a short period, resulting in the second node 345b being pulled in opposite directions (at least temporarily): pulled up by the transistor 348 and the pulled down by the transistors 332, 336. Similarly, without the transistor 352, if the second node 345b was previously storing a low value and the clear control signal C is asserted, the transistor 346 may remain activated for a short period, resulting in the first node 345a being pulled in opposite directions (at least temporarily): pulled up by the transistor 346 and the pulled down by the transistors 334, 338. Thus, by including the transistors 352, 354, which are directly controllable by the set and clear control signals S and C, any competing pull-up paths (e.g., via the transistors 346, 348) can be quickly cut off or at least weakened.

Furthermore, by providing faster operation speeds, embodiments of the present technology can enable the use of low-leakage transistors (e.g., low-leakage high-threshold-voltage transistors (LLHVT), ultra-high-threshold-voltage transistors (UHVT)). Although low-leakage transistors are typically associated with longer lengths and slower operation times compared to other types of transistors, embodiments of the present technology can enable shorter write pulses (e.g., by including the transistors 352, 354 that can quickly cut off or at least weaken competing pull-up paths), which may counterbalance any slower operation speeds associated with low-leakage transistors.

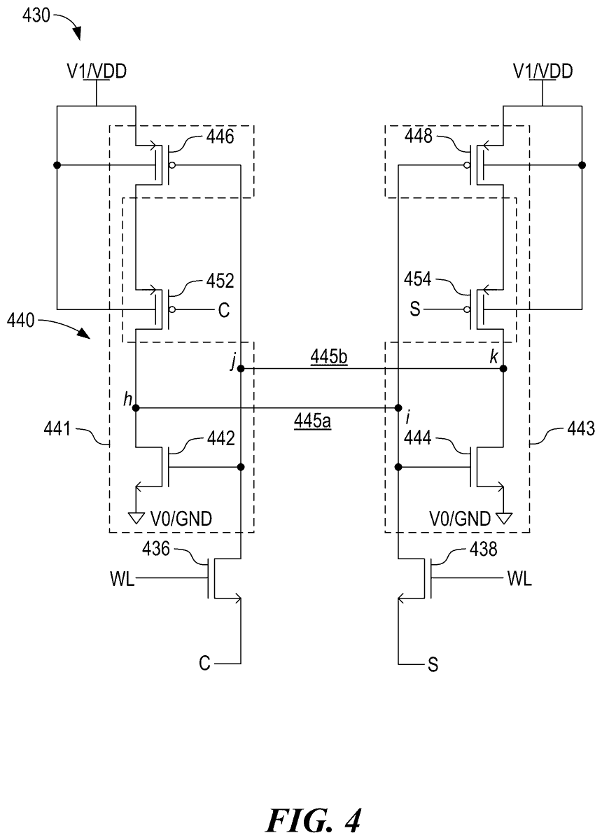

FIG. 4 is a partially schematic diagram of another bit storage circuit 430 configured in accordance with various embodiments of the present technology. It is appreciated that the bit storage circuit 430 can be an example of a bit storage circuit included in each of the pixels 230 of FIG. 2 and/or of other bit storage circuits configured in accordance with various embodiments of the present technology. In some embodiments, the bit storage circuit 430 can include an SRAM cell. For example, the bit storage circuit 430 can include a latch 440 coupled between VDD and ground, and transistors 436, 438, 452, 454.

As shown, the latch 440 and the transistors 452, 454 can be identical (or at least generally similar) in structure and/or function to the latch 340 and the transistors 352, 354, respectively, of the bit storage circuit 330 of FIG. 3 described above. For example, the latch 440 includes a pair of cross-coupled inverters. The pair of cross-coupled inverters includes a first inverter 441 having transistors 442, 446, and a second inverter 443 having transistors 444, 448. The transistor 452 can selectively couple the drain of the transistor 442 to (i) the drain of the transistor 446 and (ii) an output h of the first inverter 441, based at least in part on a second control signal C applied to a gate of the transistor 452, and the transistor 454 can selectively couple the drain of the transistor 444 to (i) the drain of the transistor 448 and (ii) an output k of the second inverter 443, based at least in part on a first control signal S. As also shown in FIG. 4, each of the transistors 446, 448, 452, 454 can include a body terminal coupled to VDD.

Unlike in the bit storage circuit 330 of FIG. 3, each of the pull-down legs of the bit storage circuit 430 of FIG. 4 includes a single (e.g., only one) transistor 436 or 438 in the illustrated embodiment, which can reduce the overall size/footprint of the bit storage circuit 430 in comparison to the bit storage circuit 330. In addition, the transistor 436 selectively couples the input j of the first inverter 441 to the second control signal C based at least in part on a row enable signal WL received at the gate of the transistor 436, and the transistor 438 selectively couples the input i of the second inverter 443 to the first control signal S based at least in part on the row enable signal WL received at the gate of the transistor 438. Stated another way, the transistor 436 includes a source coupled to receive the second control signal C, a drain coupled to the input j of the first inverter 441, and a gate coupled to receive the row enable signal WL. Similarly, the transistor 438 includes a source coupled to receive the first control signal S, a drain coupled to the input i of the second inverter 443, and a gate coupled to receive the row enable signal WL. In still other words, the transistors 438, 436 are each configured to receive the first and second control signals S and C, respectively, at their sources (e.g., as opposed to at their gates).

In the illustrated embodiment, the transistors 452, 454 comprise PMOS transistors having gates coupled to receive the second and first control signals C and S, respectively. In other embodiments, the transistors 452, 454 comprise NMOS transistors having gates coupled to receive the first and second control signals S and C, respectively. As discussed above with respect to the transistors 352, 354 of FIG. 3 and described in further detail below, the inclusion of the transistors 452, 454 can allow the use of low-leakage transistors (e.g., low-leakage high-threshold-voltage transistors (LLHVT), ultra-high-threshold-voltage transistors (UHVT)), which are typically associated with longer lengths and slower operation times compared to other types of transistors (e.g., conventional transistors).

Compared to other bit storage circuits, such as the bit storage circuit 330 of FIG. 3, the bit storage circuit 430 of FIG. 4 can be operated to write data bits onto the first and second nodes 445a, 445b with reduced power consumption. Referring momentarily back to FIG. 3 for the sake of example, when setting a data bit of “1” onto the first node 345a, the write enable signal WL and the first control signal S are asserted while the second control signal C is de-asserted such that the first node 345a is pulled up toward VDD and the second node 345b is pulled down toward ground. Because the first and second control signals S and C are applied to the gates of the transistors 332, 334, respectively, however, the voltage levels of the first and second control signals S and C (when asserted) must be greater than the threshold voltages of the transistors 332, 334 (e.g., NMOS transistors) to provide enough pull-down strength. Higher voltage levels of the first and second control signals S and C are associated with higher power consumption.

Referring back to FIG. 4, the transistor 438, 436 of the bit storage circuit 430 are coupled to receive the first and second control signals S and C, respectively, at their sources. Thus, the voltage levels of the first and second control signals S and C can be reduced in comparison to the voltage levels of the first and second control signals S and C used in the bit storage circuit 330 of FIG. 3, resulting in reduced power consumption in the bit storage circuit 430 of FIG. 4. In some embodiments, when asserted, a voltage level of the first or second control signal S or C can be between (i) approximately 40% of the voltage level of VDD and (ii) approximately 70% of the voltage level of VDD. For example, when asserted, a voltage level of the first or second control signal S or C can be between (a) approximately 50% of the voltage level of VDD and (b) approximately 60% of the voltage level of VDD. In some embodiments, the reduction in the voltage levels of the control signals S and C described above can reduce, eliminate, or minimize the risk of any potential disturbance to neighboring pixels.

In some embodiments, a data bit of “1” can be set onto a first node 445a by asserting the write enable signal WL and the first control signal S, while de-asserting the second control signal C. More specifically, when setting a data bit of “1” onto the first node 445a, the write enable signal WL and the first control signal S can be asserted and the second control signal C can be unasserted to pull up the first node 445a toward VDD and pull down the second node 445b toward ground. Prior to this write operation, however, the voltage level on the first node 445a may have been low or at ground, meaning that the transistor 448 of the second inverter 443 may be activated via the input i of the second inverter 443 at this time. Because the transistors of the latch 440 are activated by the voltage level of the first and second nodes 445a, 445b, there can be a delay in properly writing the data bits to the latch 440. For example, in embodiments in which the bit storage circuit 430 omits the transistors 452, 454, although the voltage level on the second node 445b may eventually settle to ground after the first control signal S is asserted to write the latch 440, the transistor 448 (initially or previously activated due to the first node 445a being at a low voltage state prior to the write operation) may temporarily provide a pull-up path for the second node 445b, resulting in the voltage level at the second node 445b being pulled in opposite directions (at least temporarily): pulled up toward VDD via the transistor 448 and pulled down toward ground via the transistor 444. Therefore, without the transistors 452, 454, the bit storage circuit 430 of FIG. 4 can be vulnerable to old data stored to the latch 440 contending with new data being written to the latch 440, which can lead to increased power consumption and/or slower access/write times.

The transistors 452, 454 of the bit storage circuit 430 can address this issue. More specifically, because the transistors 452, 454 are activated directly by the second and first control signals C and S, respectively, they can be activated or deactivated more quickly than the transistors 442, 446, 444, 448 of the latch 440. For example, although the transistor 448 may initially provide a pull-up path for the second node 445b when the voltage on the first node 445a is low, the transistor 454 (e.g., a PMOS transistor) can be at least partially deactivated when the first control signal S is asserted. As previously mentioned, in some embodiments, voltage levels of the first and second control signals S and C can be a fraction of the threshold voltages of the transistors 454, 452, respectively, (e.g., a fraction of a voltage level of VDD) such that asserting the first control signal S in this example may not fully deactivate the transistor 454 but may weaken the pull-up leg or path between the second node 445b and VDD. Therefore, when the first control signal S is asserted, the input j can be more pulled down toward ground and the output k can be at least partially cut off from VDD, allowing the voltage level on the second node 445b to be more easily and/or quickly pulled down toward ground without significant bitline contention. The transistor 452 can be similarly operated using the second control signal C.

Not fully deactivating the transistor 454 using the first control signal S and/or not fully deactivating the transistor 452 using the second control signal C is expected to avoid write disturb issues on neighboring, unselected bit storage circuits. For example, the bit storage circuit 430 of FIG. 4 may be positioned at row n+1 and column m in an array of bit storage circuits. Continuing with this example, to write another bit storage circuit of the same column m but a different row (e.g., row n), the row enable signal WL for row n may be asserted, the first control signal S may be asserted, and the second control signal C may be de-asserted. In addition, during the write operation for that other bit storage circuit of row n, the row enable signal WL for row n+1 (corresponding to the bit storage circuit 430) can be unasserted such that the transistors 436, 438 are deactivated. Because the first and second control signals S and C are commonly shared by all bit storage circuits of the same column m, performing the write operation on the other bit storage circuit of row n may undesirably affect the bit storage circuit 430 of row n+1 were the transistors 452 and/or 454 to be fully deactivated via assertion of the first or second control signals S or C.

As a specific example, consider the event in which a voltage level on the first node 445a of the bit storage circuit 430 is low, a voltage level on the second node 445b of the bit storage circuit 430 is high, the first control signal S is asserted to program the other bit storage circuit of row n, and assertion of the first control signal S fully deactivates the transistor 454 of the bit storage circuit 430. During the write operation for the other bit storage circuit of row n, current may leak through the transistor 444 of the bit storage circuit 430, thereby dropping the voltage on the second node 445b of the bit storage circuit 430 while the pull-up leg for the second node 445b (extending through the transistor 454 and the transistor 448 to VDD) is cut because the transistor 454 is fully deactivated when the first control signal S is asserted to program the other bit storage circuit of row n. Thus, as current leaks from the latch 440 through the transistor 444, the current on the latch 440 would not be replenished via the pull-up leg because the second node 445b is uncoupled from VDD while the transistor 454 is deactivated. As a result, the leakage current from the transistor 444 may compromise the integrity of the data stored in the bit storage circuit 430. More specifically, the leakage current from the transistor 444 can drop the voltage on the second node 445b toward a voltage that activates the transistor 446 and deactivates the transistor 442 of the first inverter 441. As the voltage on the second node 445b drops below threshold voltages of the transistors 446 and 442 of the first inverter 441, the voltage value on the first node 445a can be flipped from low (e.g., “0”) to high while the voltage value on the second node 445b can be flipped from high to low, thereby corrupting the data stored on the latch 440.

The bit storage circuit 430 of FIG. 4, however, can avoid this issue by not fully deactivating the transistors 454, 452 when the first and second controls signals S and C, respectively, are asserted. For example, because the transistor 454 of the bit storage circuit 430 in several embodiments of the present technology is not fully deactivated when the first control signal S is asserted, the pull-up leg for the second node 445b (extending through the transistor 454 and the transistor 448) is weakened but not cut when the first control signal S is asserted. As a result, the transistor 454 remains at least partially activated/enabled to conduct subthreshold current that can replenish and/or compensate for off-state leakage current from the transistor 444. The transistor 452 and the second control signal C provide a similar benefit with the second control signal C is asserted in a bit storage circuit of an unselected row.

In other embodiments of the present technology, voltage levels of the first and second control signals S and C in an asserted state can be sufficient to fully deactivate the transistor 454, 452. In at least some of these embodiments, low-leakage transistors can be used for one or more of the transistors 442, 446, 444, 448 of the latch 440 such that leakage current does not pose a substantial risk to data security while programming bit storage circuits of other rows.

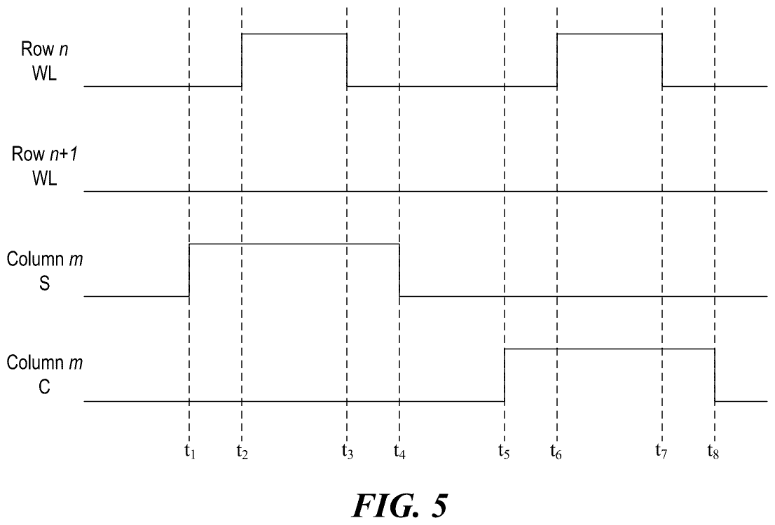

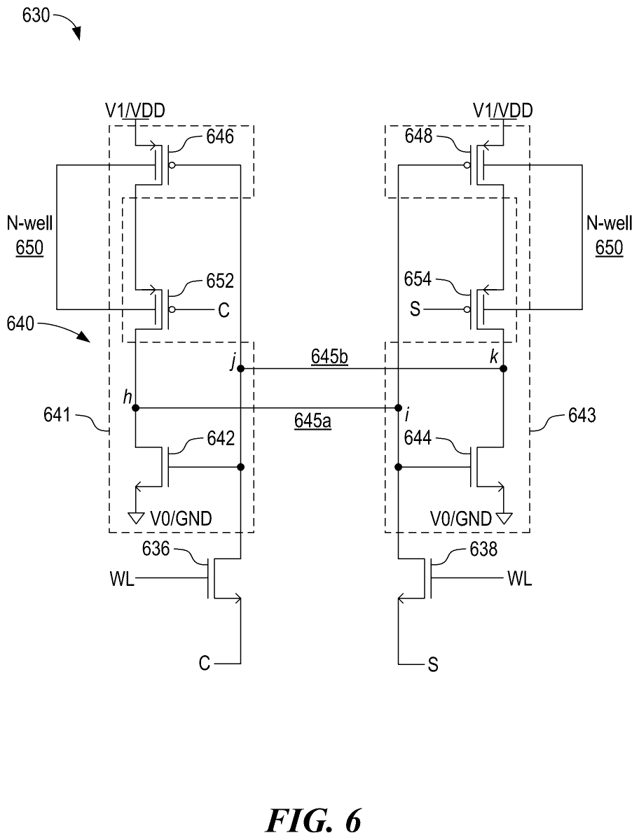

FIG. 5 is an example timing diagram for controlling a bit storage circuit in accordance with various embodiments of the present technology. The timing diagram of FIG. 5 can be an example timing diagram for the bit storage circuit 330 of FIG. 3, the bit storage circuit 430 of FIG. 4, the bit storage circuit of FIG. 6 (described in greater detail below), and/or other bit storage circuits configured in accordance with various embodiments of the present technology. The illustrated timing diagram graphs during, for example, a write operation and a clear/reset operation for row n, the write enable signal WL for row n, the write enable signal WL for a neighboring row (row n+1), the first control signal S on column m, and the second control signal C on column m. As discussed in further detail herein, the timing diagram of FIG. 5 can illustrate a method for writing and/or clearing/resetting a latch (e.g., the latch 440) of a bit storage circuit (e.g., the bit storage circuit 430).

A method for writing the latch is shown between time t₁ and time t₄ in the illustrated embodiment. As illustrated, the second control signal C for column m and the write enable signal WL for row n+1 remain unasserted for the entire duration of time between time t₁ and time t₄. Furthermore, at time t₁, the first control signal S can be asserted for column m. As previously mentioned, the first control signal S may be shared by the entire column m. As such, the first control signal S may be asserted in a plurality of bit storage circuits that are arranged in the same column m but that are each positioned in different rows from one another. Asserting the first control signal S may include activating one or more transistors (e.g., the transistor 332) of the bit storage circuit (e.g., the bit storage circuit 330).

Writing the latch can further include, at time t₁, cutting or weakening a pull-up path of the bit storage circuit. In some embodiments, cutting or weakening the pull-up path of the bit storage circuit includes applying the asserted first control signal S to a gate of a transistor (e.g., the transistor 354, the transistor 454) in the pull-up path of the bit storage circuit (e.g., such that the transistor is deactivated, partially deactivated, or partially activated).

At time t₂, the write enable signal WL can be asserted for row n. Referring to FIG. 3 for the sake of example, asserting the write enable signal WL when the first control signal S is also asserted can selectively couple an input of a first inverter (e.g., the input j of the first inverter 341) and an output of a second inverter (e.g., the output k of the second inverter 343) of the latch to a first voltage (e.g., ground) such that the input of the first inverter and the output of the second inverter are pulled down toward the first voltage. Referring now to FIG. 4 for the sake of example, asserting the write enable signal WL when the first control signal S is also asserted and the second control signal C is unasserted can (a) selectively couple an input of a first inverter (e.g., the input j of the first inverter 441) and an output of a second inverter (e.g., the output k of the second inverter 443) to a voltage level of the unasserted second control signal C such that the input of the first inverter and the output of the second inverter are pulled down toward a first voltage level (e.g., ground or the voltage level of the unasserted second control signal C), and (b) selectively couple an input of the second inverter (e.g., the input i of the second inverter 443) and an output of the first inverter (e.g., the output h of the first inverter 441) to a voltage level of the asserted first control signal S such that the input of the second inverter and the output of the first inverter are pulled up toward a second voltage level (e.g., VDD or the voltage level of the asserted first control signal S).

At time t₃, the write enable signal WL can be de-asserted for row n. Referring to FIG. 3, de-asserting the write enable signal WL can include selectively uncoupling the input of the first inverter and the output of the second inverter from the first voltage (e.g., ground). Referring to FIG. 4, de-asserting the write enable signal WL can include (a) selectively uncoupling the input of the first inverter and the output of the second inverter from the voltage level of the unasserted second control signal C, and (b) selectively uncoupling the input of the second inverter and the output of the first inverter from the voltage level of the asserted first control signal S.

At time t₄, the first control signal S can be de-asserted for column m. De-asserting the first control signal S can reactivate (or fully activate) a transistor (e.g., the transistor 354, the transistor 454) in a pull-up path of the bit storage circuit. Referring to FIG. 3, de-asserting the first control signal S can include deactivating one or more transistors (e.g., the transistor 332) of a bit storage circuit.

As shown in FIG. 5, the first control signal S is asserted at time t₁ before asserting the write enable signal WL at time t₂, and is de-asserted at time t₄ after de-asserting the write enable signal WL at time t₃. This can ensure that a voltage level of the asserted first control signal S is high for an entire period of time that the voltage level of the asserted first control signal S is selectively coupled to the input i of the second inverter and the output h of the first inverter via the transistor 438 of the bit storage circuit 430.

Resetting or clearing the latch is shown between time t₅ and time t₈ in the illustrated embodiment. As illustrated, the first control signal S for column m and the write enable signal WL for row n+1 remain unasserted for the entire duration of time between time t₅ and time t₈. Furthermore, at time t₅, the second control signal C can be asserted for column m. As previously mentioned, the second control signal C may be shared by the entire column m. As such, the second control signal C may be asserted in a plurality of bit storage circuits that are arranged in the same column m but that are each positioned in different rows from one another. Asserting the second control signal C may include activating one or more transistors (e.g., the transistor 334) in one or more pull-down legs of the bit storage circuit (e.g., the bit storage circuit 330).

Clearing the latch can further include, at time t₅, cutting or weakening a pull-up path of the bit storage circuit. In some embodiments, cutting or weakening the pull-up leg of the bit storage circuit includes applying the asserted second control signal C to a gate of a transistor (e.g., the transistor 352, the transistor 452) in the pull-up path of the bit storage circuit (e.g., such that the transistor is deactivated, partially deactivated, or partially activated).

At time t₆, the write enable signal WL can be asserted for row n. Referring to FIG. 3 for the sake of example, asserting the write enable signal WL when the control signal C is also asserted can selectively couple an input of a second inverter (e.g., the input i of the second inverter 343) and an output of a first inverter (e.g., the output h of the first inverter 341) of the latch to the first voltage (e.g., ground) such that the input of the second inverter and the output of the first inverter 441 are pulled down toward the first voltage. Referring now to FIG. 4 for the sake of example, asserting the write enable signal WL when the second control signal C is also asserted and the first control signal S is unasserted can (a) selectively couple an input of a second inverter (e.g., the input i of the second inverter 443) and an output of a first inverter (e.g., the output h of the first inverter 441) to a voltage level of the unasserted first control signal S such that the input of the first inverter and the output of the second inverter are pulled down toward a first voltage level (e.g., ground or the voltage level of the unasserted first control signal S), and (b) selectively couple an input of the first inverter (e.g., the input j of the first inverter 441) and an output of the second inverter (e.g., the output k of the second inverter 443) to a voltage level of the asserted second control signal C such that the input of the first inverter and the output of the second inverter are pulled up toward a second voltage level (e.g., VDD or the voltage level of the asserted second control signal C).

At time t₇, the write enable signal WL can be de-asserted for row n. Referring to FIG. 3, de-asserting the write enable signal WL can include selectively uncoupling the input of the second inverter and the output of the first inverter from the first voltage (e.g., ground). Referring to FIG. 4, de-asserting the write enable signal WL can include (a) selectively uncoupling the input of the second inverter and the output of the first inverter from the voltage level of the unasserted first control signal S, and (b) selectively uncoupling the input of the first inverter and the output of the second inverter from the voltage level of the asserted second control signal C.

At time t₈, the second control signal C can be de-asserted for column m. De-asserting the second control signal C can reactivate (or fully activate) a transistor (e.g., the transistor 352, the transistor 452) in a pull-up path of the bit storage device. Referring to FIG. 3, de-asserting the second control signal C can include deactivating one or more transistors (e.g., the transistor 334) of a bit storage circuit.

As shown in FIG. 5, the second control signal C is asserted at time t₅ before asserting the write enable signal WL at time t₆, and is de-asserted at time t₈ after de-asserting the write enable signal WL at time t₇. This can ensure that a voltage level of the asserted second control signal C is high for an entire period of time that the voltage level of the asserted second control signal C is selectively coupled to the input j of the first inverter and the output k of the second inverter via the transistor 436 of the bit storage circuit 430. Although the write enable signal WL is shown in FIG. 5 as being (a) asserted after asserting the control signal C and (b) de-asserted before de-asserting the control signal C, the present technology is not so limited. For example, for at least the bit storage circuit 330 of FIG. 3, the write enable signal WL can be asserted before or at a same time as asserting the control signal C. As another example, for at least the bit storage circuit 330 of FIG. 3, the write enable signal WL can be de-asserted after or at a same time as de-asserting the control signal C.

In some embodiments, the first and second control signals S and C can be asserted for a duration of 10 ns or less, 8 ns or less, 5 ns or less, 2.5 ns or less, 2 ns or less, 1.5 ns or less, or 1 ns or less. In these and other embodiments, the duration of each write pulse (corresponding to how long the write enable signal WL is asserted for each pulse) can be 5 ns or less, 4 ns or less, 3 ns or less, 2 ns or less, or 1 ns or less.

FIG. 6 is a partially schematic diagram of another bit storage circuit 630 configured in accordance with various embodiments of the present technology. It is appreciated that the bit storage circuit 630 can be an example of a bit storage circuit included in each of the pixels 230 of FIG. 2, and/or of other bit storage circuits configured in accordance with various embodiments of the present technology. In some embodiments, the bit storage circuit 630 can include an SRAM cell. For example, the bit storage circuit 630 can include a latch 640 coupled between VDD and ground, and transistors 636, 638, 652, 654.

As shown, the latch 640 and the transistors 636, 638, 652, 654 can be identical to (or at least generally similar in) structure and/or function to the latch 440 and the transistors 436, 438, 452, 454, respectively, of the bit storage circuit 430 in FIG. 4. For example, the latch 640 includes a pair of cross-coupled inverters. The pair of cross-coupled inverters includes a first inverter 641 having transistors 642, 646, and a second inverter 643 having transistors 644, 648. The transistor 652 can selectively couple the drain of the transistor 642 to (i) the drain of the transistor 646 and (ii) an output h of the first inverter 641, based at least in part on a state of a second control signal C applied to a gate of the transistor 652, and the transistor 654 can selectively couple the drain of the transistor 644 to (i) the drain of the transistor 648 and (ii) an output k of the second inverter 643, based at least in part on a state of a first control signal S applied to a gate of the transistor 654. The input j of the first inverter 641 and the output k of the second inverter 643 can be coupled to a second node 645b, and the input i of the second inverter 643 and the output h of the first inverter 641 can be coupled to a first node 645a.

Unlike in the bit storage circuit 430 of FIG. 4, however, the body terminals of the transistors 646, 648, 652, 654 are part of (or are coupled to) a dynamic N-well 650. For example, the body terminals of the transistors 646, 652 can be coupled together, and the body terminals of the transistors 648, 654 can be coupled together. A process (e.g., a silicon-on-insulator (SOI) process) used during manufacturing or fabrication of the bit storage circuit 630 can allow the voltage level of the dynamic N-well 650 to be adjusted, such as to ground the dynamic N-well 650 or to bias the dynamic N-well 650 to VDD.

As a specific example, by virtue of the dynamic N-well 650, the body terminals of the transistors 646, 648, 652, 654 can be selectively connected or couplable (i) to ground based at least in part on a first operation mode of the bit storage circuit 630 and (ii) to VDD based at least in part on a second operation mode of the bit storage circuit 630. For example, in the first operation mode, the body terminals of the transistors 646, 652 can be selectively coupled to ground via an NMOS transistor (not shown) and a corresponding control signal. Continuing with this example, in the second operation mode, the body terminals of the transistor 646, 652 can be selectively coupled to VDD via a PMOS transistor (not shown) and a corresponding control signal. The corresponding control signal for the NMOS transistor and the corresponding control signal for the PMOS control signal can be the same signal, or two different signals that are operated such that the NMOS transistor and the PMOS transistor are not in conduction (e.g., activated) at the same time. In some embodiments, the NMOS transistor and the PMOS transistors are located in periphery circuitry (e.g., outside of the bit storage circuit 630) and/or may be shared by multiple bit storage circuits.

In some embodiments, the first operation mode can be an active mode of the bit storage circuit 630 such that the N-well is grounded while the bit storage circuit 630 is operated in the active mode. In these and other embodiments, the second operation mode can be a standby or sleep mode of the bit storage circuit 630 such that the N-well is biased to VDD (or another voltage) while the bit storage circuit 630 is in the standby/sleep mode. By grounding the N-well during the active mode, the duration of each write pulse can be reduced compared to, for example, the bit storage circuit 430 of FIG. 4 (e.g., from approximately 2 ns to approximately 1.5 ns). Shorter write pulses can result in reduced power consumption and/or faster write operations. Also, by biasing the N-well to VDD (or another voltage) during the standby or sleep mode, standby current consumed by the bit storage circuit 630 can be reduced, leading to further reductions in power consumption.

Thus, referring back to the method discussed with reference to the timing diagram of FIG. 5, the method can further include, based at least in part on the bit storage circuit operating in an active mode, grounding the dynamic N-well. Additionally, or alternatively, the method can further include, based at least in part on the bit storage circuit operating in a sleep mode or a standby mode, biasing the N-well to VDD or another voltage.

### C. Conclusion

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.” Also, the terms “connect” and “couple” are used interchangeably herein and refer to both direct and indirect connections or couplings. For example, where the context permits, element A “connected” or “coupled” to element B can refer (i) to A directly “connected” or directly “coupled” to B and/or (ii) to A indirectly “connected” or indirectly “coupled” to B.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

1. A bit storage circuit, comprising:
a latch having a pair of cross-coupled inverters, the pair of cross-coupled inverters including a first inverter and a second inverter;
a first transistor having a source coupled to receive a first control signal, a drain coupled to an input of the first inverter, and a gate coupled to receive a wordline select control signal; and
a second transistor having a source coupled to receive a second control signal different from the first control signal, a drain coupled to an input of the second inverter, and a gate coupled to receive the wordline select control signal.

2. The bit storage circuit of claim 1, wherein:
the first inverter includes
a third transistor having a source coupled to a supply voltage, a gate coupled to the input of the first inverter, and a drain, and
a fourth transistor having a source coupled to ground, a gate coupled to the input of the first inverter, and a drain; and
the bit storage circuit further comprises a fifth transistor selectively coupling the drain of the third transistor to the drain of the fourth transistor.

3. The bit storage circuit of claim 2, wherein the fifth transistor includes a source coupled to the drain of the third transistor, a drain coupled to the drain of the fourth transistor, and a gate coupled to receive the first control signal.

4. The bit storage circuit of claim 2, wherein:
the second inverter includes
sixth transistor having a source coupled to a supply voltage, a gate coupled to the input of the second inverter, and a drain, and
a seventh transistor having a source coupled to ground, a gate coupled to the input of the second inverter, and a drain; and
the bit storage circuit further comprises an eighth transistor selectively coupling the drain of the sixth transistor to the drain of the seventh transistor.

5. The bit storage circuit of claim 4, wherein the eighth transistor includes a source coupled to the drain of the sixth transistor, a drain coupled to a drain of the seventh transistor, and a gate coupled to receive the second control signal.

6. The bit storage circuit of claim 4, wherein:
the sixth transistor includes a body terminal coupled to the supply voltage; and
the eighth transistor includes a body terminal coupled to the supply voltage.

7. The bit storage circuit of claim 4, wherein:
the sixth transistor includes a body terminal that (a) is selectively couplable to ground based at least in part on a first operation mode of the bit storage circuit and (b) is selectively couplable to the supply voltage based at least in part on a second operation mode of the bit storage circuit; and
the eighth transistor includes a body terminal that (a) is selectively couplable to ground based at least in part on the first operation mode of the bit storage circuit and (b) is selectively couplable to the supply voltage based at least in part on the second operation mode of the bit storage circuit.

8. The bit storage circuit of claim 7, wherein the first operation mode is an active mode of the bit storage circuit, and wherein the second operation mode is a standby or sleep mode of the bit storage circuit.

9. The bit storage circuit of claim 2, wherein:
the third transistor includes a body terminal that (a) is selectively couplable to ground based at least in part on a first operation mode of the bit storage circuit and (b) is selectively couplable to the supply voltage based at least in part on a second operation mode of the bit storage circuit; and
the fifth transistor includes a body terminal that (a) is selectively couplable to ground based at least in part on the first operation mode of the bit storage circuit and (b) is selectively couplable to the supply voltage based at least in part on the second operation mode of the bit storage circuit.

10. The bit storage circuit of claim 9, wherein the first operation mode is an active mode of the bit storage circuit, and wherein the second operation mode is a standby or sleep mode of the bit storage circuit.

11. The bit storage circuit of claim 2, wherein:
the third transistor includes a body terminal coupled to the supply voltage; and
the fifth transistor includes a body terminal coupled to the supply voltage.

12. The bit storage circuit of claim 1, wherein, when asserted, a voltage level of the first control signal and/or a voltage level of the second control signal is/are between approximately 40% of a voltage level of a supply voltage and approximately 70% of the voltage level of the supply voltage.

13. A bit storage circuit, comprising:
a first inverter having an input, an output, a first transistor, and a second transistor, wherein
first transistor includes a source coupled to a supply voltage, a gate coupled to the input of the first inverter, and a drain, and
the second transistor includes a source coupled to ground, a gate coupled to the input of the first inverter, and a drain coupled to the output of the first inverter;
a third transistor selectively coupling the drain of the first transistor to the drain of the second transistor based at least in part on a first control signal received at a gate of the third transistor;
a second inverter having an input coupled to the output of the first inverter, an output coupled to the input of the first inverter, a fourth transistor, and a fifth transistor, wherein
fourth transistor includes a source coupled to the supply voltage, a gate coupled to the input of the second inverter, and a drain, and
the fifth transistor includes a source coupled to ground, a gate coupled to the input of the second inverter, and a drain coupled to the output of the second inverter; and
a sixth transistor selectively coupling the drain of the fourth transistor to the drain of the fifth transistor based at least in part on a second control signal received at a gate of the sixth transistor, wherein the second control signal is different from the first control signal.

14. The bit storage circuit of claim 13, further comprising:
a seventh transistor selectively coupling a third control signal to the input of the first inverter based at least in part on a write enable signal received at a gate of the seventh transistor; and
an eighth transistor selectively coupling a fourth control signal to the input of the second inverter based at least in part on the write enable signal received at a gate of the eighth transistor.

15. The bit storage circuit of claim 14, wherein the third control signal is the first control signal, and wherein the fourth control signal is the second control signal.

16. The bit storage circuit of claim 13, further comprising:
a seventh transistor coupled between the input of the first inverter and ground, the seventh transistor including a gate coupled to receive the second control signal;
an eighth transistor selectively coupling the seventh transistor to the input of the first inverter based at least in part on a write enable signal received at a gate of the eighth transistor;
a ninth transistor coupled between the input of the second inverter and ground, the ninth transistor including a gate coupled to receive the first control signal; and
a tenth transistor selectively coupling the ninth transistor to the input of the second inverter based at least in part on the write enable signal received at a gate of the tenth transistor.

17. The bit storage circuit of claim 13, wherein the third transistor and the sixth transistor each include a body terminal coupled to the supply voltage.

18. The bit storage circuit of claim 13, wherein:
the first transistor includes a body terminal that (a) is selectively couplable to ground based at least in part on a first operation mode of the bit storage circuit and (b) is selectively couplable to the supply voltage based at least in part on a second operation mode of the bit storage circuit; and
the third transistor includes a body terminal that (a) is selectively couplable to ground based at least in part on the first operation mode of the bit storage circuit and (b) is selectively couplable to the supply voltage based at least in part on the second operation mode of the bit storage circuit.

19. The bit storage circuit of claim 18, wherein:
the fourth transistor includes a body terminal that (a) is selectively couplable to ground based at least in part on the first operation mode of the bit storage circuit and (b) is selectively couplable to the supply voltage based at least in part on the second operation mode of the bit storage circuit; and
the sixth transistor includes a body terminal that (a) is selectively couplable to ground based at least in part on the first operation mode of the bit storage circuit and (b) is selectively couplable to the supply voltage based at least in part on the second operation mode of the bit storage circuit.

20. The bit storage circuit of claim 18, wherein the first operation mode is an active mode of the bit storage circuit, and wherein the second operation mode is a standby or sleep mode of the bit storage circuit.

21. A method, comprising:
writing a latch of a bit storage circuit, wherein the latch includes a pair of cross-coupled inverters, and wherein writing the latch includes
asserting a control signal at a first time, and
selectively coupling, at a second time occurring after the first time, a voltage level corresponding to the asserted control signal to an input of an inverter of the pair of cross-coupled inverters.

22. The method of claim 21, wherein writing the latch further includes
selectively uncoupling, at a third time occurring after the second time, the voltage level corresponding to the asserted control signal from the input of the inverter; and
de-asserting the control signal at a fourth time occurring after the third time.

23. The method of claim 21, wherein selectively coupling the voltage level corresponding to the asserted control signal to the input of the inverter includes selectively coupling the voltage level to the input of the inverter such that an output of the inverter is pulled up toward a voltage level corresponding to a supply voltage.

24. The method of claim 21, wherein writing the latch includes weakening a pull-up leg of the inverter.

25. The method of claim 21, wherein:
the inverter is a first inverter, the control signal is a first control signal, and the voltage level is a first voltage level;
the method further comprises clearing the latch; and
clearing the latch includes
asserting a second control signal at a third time, and
selectively coupling, at a fourth time occurring after the third time, a second voltage level corresponding to the asserted second control signal to an input of a second inverter of the pair of cross-coupled inverters.

26. The method of claim 25, wherein clearing the latch further includes
selectively uncoupling, at a fifth time occurring after the fourth time, the second voltage level corresponding to the second control signal from the input of the second inverter; and
de-asserting the second control signal at a sixth time occurring after the fifth time.

27. The method of claim 25, wherein clearing the latch includes weakening a pull-up leg of the second inverter.

28. The method of claim 25, wherein selectively coupling the second voltage level corresponding to the second control signal to the input of the second inverter includes selectively coupling the second voltage level to the input of the second inverter such that an output of the second inverter is pulled down toward ground.

29. The method of claim 21, further comprising, based at least in part on the bit storage circuit operating in an active mode, biasing a body terminal of each of one or more transistors of the inverters of the pair toward a voltage level corresponding to a supply voltage.

30. The method of claim 21, further comprising, based at least in part on the bit storage circuit operating in a sleep mode or a standby mode, biasing a body terminal of each of one or more transistors of the inverters of the pair toward a voltage level corresponding to ground.

31. The method of claim 21, wherein selectively coupling the voltage level corresponding to the asserted control signal to the input of the first inverter includes selectively coupling the voltage level to the input of the first inverter for a duration of 10 ns or less.
